(19) United States
(12) Patent Application Publication
(10) Pub. No.: US 2017/0242331 A1
(43) Pub. Date: Aug. 24, 2017

(54) PHASE SHIFT MASK AND MANUFACTURING METHOD THEREOF

(71) Applicant: Powerchip Technology Corporation, Hsinchu (TW)

(72) Inventor: Yi-Kai Lai, Taoyuan City (TW)

(21) Appl. No.: 15/134,394

(22) Filed: Apr. 21, 2016

(30) Foreign Application Priority Data
Feb. 19, 2016 (TW) 105104866

(51) Int. Cl. G03F 1/26

(52) U.S. Cl. CPC G03F 1/26

(57) ABSTRACT

A phase shift mask including a substrate, a phase shift layer and a transparent layer is provided. The phase shift layer is disposed on the substrate and has an opening. The transparent layer is disposed in the opening. The phase shift mask can have a large DOF window.

### CROSS-REFERENCE TO RELATED APPLICATION

This application claims the priority benefit of Taiwan application serial no. 105104866, filed on Feb. 19, 2016. The entirety of the above-mentioned patent application is hereby incorporated by reference herein and made a part of this specification.

### BACKGROUND OF THE INVENTION

Field of the Invention

The invention relates to a mask and a manufacturing method thereof, and particularly relates to a phase shift mask and a manufacturing method thereof.

Description of Related Art

In a semiconductor manufacturing process, photolithography technique plays a very important role, and processes such as etching, doping, etc., are all implemented through the photolithography process. However, in the photolithography process, a resolution of exposure is an important indicator of photolithography quality. The photolithography technique of a phase shift mask (PSM) is a technique developed in order to obtain a better resolution.

Even if the PSM is used, since a pattern in an isolation region is relatively loose, it is liable to have a problem of inadequate depth of focus (DOF) widow, which causes a poor pattern transfer capability. Therefore, in the industry, the PSM with a sub-resolution assistant feature (SRAF) is developed to resolve the problem of inadequate DOF window.

However, since the design of the SRAF is limited by space, not any pattern on the photomask can be added with the SRAF to increase the DOF window. Moreover, the SRAF may also have a problem of print out.

Therefore, how to further increase the DOF window of the PSM is still an important problem required to be resolved in the industry.

### SUMMARY OF THE INVENTION

The invention is directed to a phase shift mask, which has a larger depth of focus (DOF) window.

The invention is directed to a manufacturing method of a phase shift mask, where the manufactured phase shift mask has better pattern transfer capability.

The invention provides a phase shift mask including a substrate, a phase shift layer and a transparent layer. The phase shift layer is disposed on the substrate and has an opening. The transparent layer is disposed in the opening.

In an embodiment of the invention, in the aforementioned phase shift mask, a material of the phase shift layer is, for example, metal silicide, metal fluoride, metal silicon oxide, metal silicon nitride, metal silicon oxynitride, metal silicon carbon oxide, metal silicon carbonitride, metal silicon oxycarbonitride, alloy thin-layer, metal thin-layer or a combination thereof.

In an embodiment of the invention, in the aforementioned phase shift mask, an extinction coefficient of the transparent layer is, for example, 0.

In an embodiment of the invention, in the aforementioned phase shift mask, a refractive index of the transparent layer is, for example, greater than 1.

In an embodiment of the invention, in the aforementioned phase shift mask, the transparent layer, for example, has a planar surface.

In an embodiment of the invention, in the aforementioned phase shift mask, a height of the transparent layer is higher than, equal to or lower than a height of the phase shift layer.

In an embodiment of the invention, in the aforementioned phase shift mask, a material of the transparent layer is, for example, a crosslinking material or silicon dioxide.

In an embodiment of the invention, in the aforementioned phase shift mask, the crosslinking material is, for example, hybrid organic siloxane polymer (HOSP), methyl silsesquioxane (MSQ) or hydrogen silsesquioxane (HSQ).

In an embodiment of the invention, the aforementioned phase shift mask can be used for forming a pattern in an isolation region.

The invention provides a manufacturing method of a phase shift mask, which includes following steps. A phase shift layer is formed on a substrate, where the phase shift layer has an opening. A transparent layer is formed in the opening.

In an embodiment of the invention, in the aforementioned manufacturing method of the phase shift mask, an extinction coefficient of the transparent layer is, for example, 0.

In an embodiment of the invention, in the aforementioned manufacturing method of the phase shift mask, a refractive index of the transparent layer is, for example, greater than 1.

In an embodiment of the invention, in the aforementioned manufacturing method of the phase shift mask, a method for forming the transparent layer includes followings steps. A transparent material layer is formed on the phase shift layer, and the transparent material layer is filled in the opening. A partial irradiation process is performed to the transparent material layer in a region of the opening, such that a crosslinking degree of the transparent material layer in the region of the opening is greater than a crosslinking degree of the transparent material layer outside the region of the opening. A developing process is performed to remove the transparent material layer that is not processed with the partial irradiation process.

In an embodiment of the invention, in the aforementioned manufacturing method of the phase shift mask, a bonding structure of a component of the transparent material layer that is not processed with the partial irradiation process is, for example, a cage structure, and a bonding structure of the component of the transparent material layer processed with the partial irradiation process is, for example, a network structure.

In an embodiment of the invention, in the aforementioned manufacturing method of the phase shift mask, the partial irradiation process is, for example, an electron beam irradiation process.

In an embodiment of the invention, in the aforementioned manufacturing method of the phase shift mask, a method for forming the transparent layer includes following steps. A transparent material layer is formed on the phase shift layer, and the transparent material layer is filled in the opening. A patterned photoresist layer is formed on the transparent material layer above the opening. The transparent material layer uncovered by the patterned photoresist layer is removed. The patterned photoresist layer is removed.

In an embodiment of the invention, the aforementioned manufacturing method of the phase shift mask further includes performing a planarization process to the transparent material layer before forming the patterned photoresist layer.

In an embodiment of the invention, in the aforementioned manufacturing method of the phase shift mask, the planarization process is, for example, a chemical mechanical polishing process.

In an embodiment of the invention, in the aforementioned manufacturing method of the phase shift mask, in a photolithography process used for forming the patterned photoresist layer, an adopted exposure process is, for example, a partial irradiation process.

In an embodiment of the invention, in the aforementioned manufacturing method of the phase shift mask, the partial irradiation process is, for example, an electron beam irradiation process.

According to the above descriptions, in the phase shift mask and the manufacturing method thereof, since the transparent layer is disposed in the opening of the phase shift layer, and the transparent layer may decrease an attenuation magnitude of an exposure light, the phase shift mask may have a larger DOF window, so as to achieve better pattern transfer capability.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a phase shift mask according to an embodiment of the invention.

FIG. 2A to FIG. 2C are cross-sectional views of a manufacturing flow of the phase shift mask of FIG. 1.

FIG. 3A to FIG. 3D are cross-sectional views of another manufacturing flow of the phase shift mask of FIG. 1.

### DESCRIPTION OF EMBODIMENTS

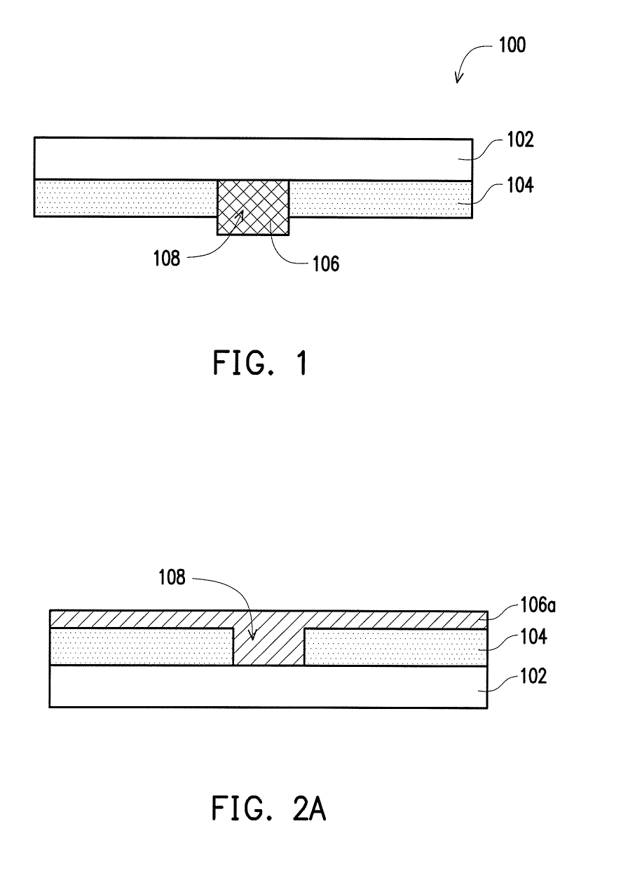

FIG. 1 is a cross-sectional view of a phase shift mask according to an embodiment of the invention.

Referring to FIG. 1, the phase shift mask 100 includes a substrate 102, a phase shift layer 104 and a transparent layer 106. The substrate 102 is, for example, a transparent substrate. A material of the substrate 102 is, for example, quartz. The phase shift mask 100 can be used to form a pattern in an isolation region. Compared to a dense region, the pattern in the isolation region is relatively loose.

The phase shift layer 104 is disposed on the substrate 102, and has an opening 108. The pattern of the opening 108 is, for example, a pattern used for forming a contact hole in the isolation region in the subsequent process. The opening 108 may expose the substrate 102. A material of the phase shift layer 104 is, for example, metal silicide, metal fluoride, metal silicon oxide, metal silicon nitride, metal silicon oxynitride, metal silicon carbon oxide, metal silicon carbonitride, metal silicon oxycarbonitride, alloy thin-layer, metal thin-layer or a combination thereof. A light transmittance of the phase shift layer 104 is, for example, 4%-20%. In the present embodiment, the material of the phase shift layer 104 is exemplified as molybdenum silicide, and the light transmittance of the phase shift layer 104 is exemplified as 6%.

The transparent layer 106 is disposed in the opening 108. The transparent layer 106 may decrease an attenuation magnitude of an exposure light to increase a depth of focus (DOF) widow of the phase shift mask 100. An extinction coefficient of the transparent layer 106 is, for example, 0 (i.e. the light transmittance is 100%). A refractive index of the transparent layer 106 is, for example, greater than 1. The transparent layer 106, for example, has a planar surface, such that the transparent layer 106 has better optical characteristics. A height of the transparent layer 106 can be higher than, equal to or lower than a height of the phase shift layer 104. In the present embodiment, the height of the transparent layer 106 is, for example, higher than the height of the phase shift layer 104. A material of the transparent layer 106 is, for example, a crosslinking material or silicon dioxide. The crosslinking material is, for example, hybrid organic siloxane polymer (HOSP), methyl silsesquioxane (MSQ) or hydrogen silsesquioxane (HSQ).

According to the above description, it is known that in the phase shift mask 100, since the transparent layer 106 is disposed in the opening 108 of the phase shift layer 104, and the transparent layer 106 may decrease the attenuation magnitude of the exposure light, the phase shift mask 100 may have a larger DOF window, so as to achieve better pattern transfer capability.

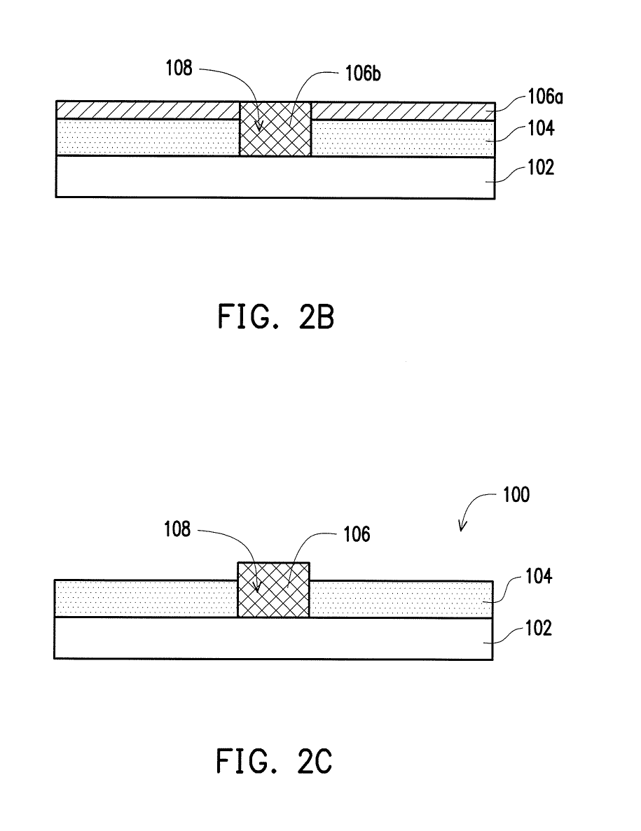

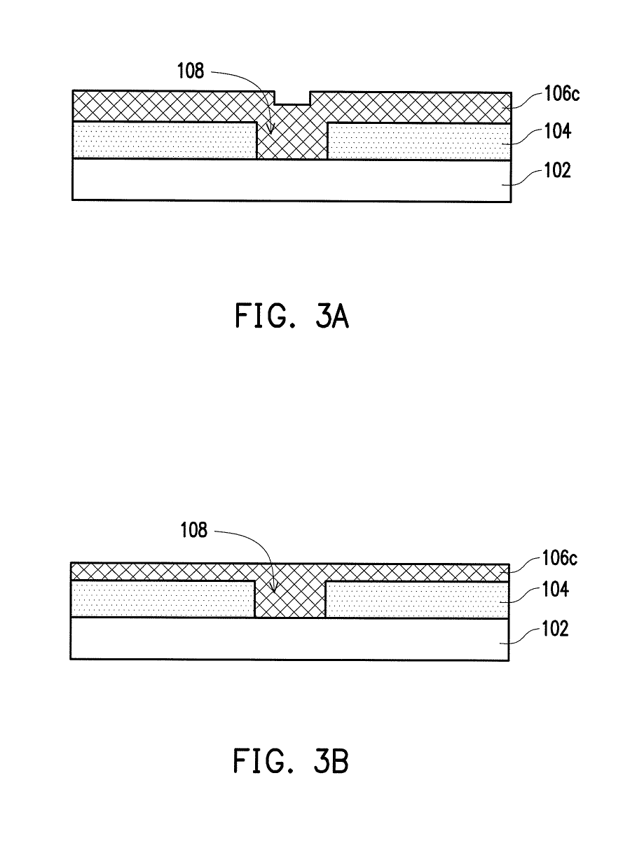

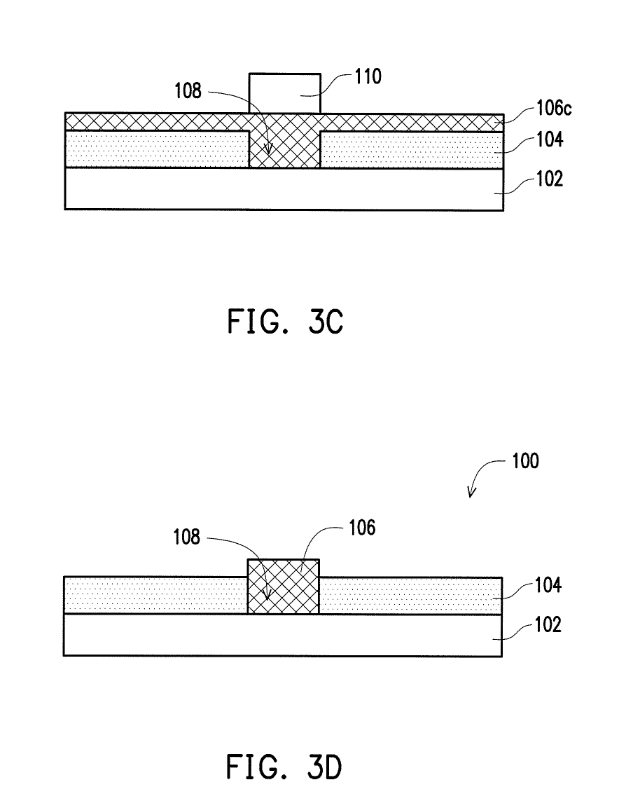

Then, the embodiment of FIG. 2A to FIG. 2C and the embodiment of FIG. 3A to FIG. 3F are provided to describe a manufacturing method of the phase shift mask 100, though the manufacturing method of the phase shift mask 100 is not limited thereto.

FIG. 2A to FIG. 2C are cross-sectional views of a manufacturing flow of the phase shift mask of FIG. 1.

Referring to FIG. 2A, the phase shift layer 104 is formed on the substrate 102, wherein the phase shift layer 104 has the opening 108. The material and the light transmittance of the phase shift layer 104 have been described in detail in the embodiment of FIG. 1, so that details thereof are not repeated. The method for forming the phase shift layer 104 is, for example, a chemical vapor deposition method or a physical vapor deposition method. The method for forming the opening 108 is, for example, to perform a patterning process to the phase shift layer 104.

A transparent material layer 106a is formed on the phase shift layer 104, and the transparent material layer 106a is filled in the opening 108. In the present embodiment, a material of the transparent material layer 106a is exemplified as a crosslinking material. The crosslinking material is, for example, hybrid organic siloxane polymer (HOSP), methyl silsesquioxane (MSQ) or hydrogen silsesquioxane (HSQ). The method for forming the transparent material layer 106a is, for example, a spin coating method.

Referring to FIG. 2B, a partial irradiation process is performed to the transparent material layer 106a in the region of the opening 108 to form a transparent material layer 106b. Through the partial irradiation process, a crosslinking degree of the transparent material layer 106b in the region of the opening 108 is greater than a crosslinking degree of the transparent material layer 106a outside the region of the opening 108. The partial irradiation process is, for example, an electron beam irradiation process.

In the present embodiment, a bonding structure of the component of the transparent material layer 106a is exemplified as a cage structure. In this case, after the partial irradiation process is performed, the bonding structure of the component of the transparent material layer 106a that is not processed with the partial irradiation process is, for example, the cage structure, and a bonding structure of the component of the transparent material layer 106b processed with the partial irradiation process is, for example, a network structure.

Referring to FIG. 2C, a developing process is performed to remove the transparent material layer 106a that is not processed with the partial irradiation process, and the phase shift mask 100 is fabricated by using the transparent material layer 106b to form the transparent layer 106 in the opening 108. The extinction coefficient of the transparent layer 106 is, for example, 0. The refractive index of the transparent layer 106 is, for example, greater than 1.

In detail, during the process of the developing process, a developer can be adapted to remove the transparent material layer 106a with lower crosslinking degree, and keep the transparent material layer 106b with higher crosslinking degree. Moreover, the developer adopted in the developing process can be different along with different materials of the transparent material layer 106a. For example, when the material of the transparent material layer 106a is the HOSP, propyl acetate can be selected as the developer. When the material of the transparent material layer 106a is the MSQ, alcohol can be selected as the developer. When the material of the transparent material layer 106a is the HSQ, tetramethylammonium hydroxide (TMAH) can be selected as the developer.

According to the above embodiment, it is known that the phase shift mask 100 can be easily fabricated according to the above method, and the attenuation magnitude of the exposure light is decreased by disposing the transparent layer 106 in the opening 108 of the phase shift layer 104, so that the phase shift layer 100 may have larger DOF window, so as to achieve better pattern transfer capability.

FIG. 3A to FIG. 3D are cross-sectional views of another manufacturing flow of the phase shift mask of FIG. 1.

Referring to FIG. 3A, the phase shift layer 104 is formed on the substrate 102, wherein the phase shift layer 104 has the opening 108. The material and the light transmittance of the phase shift layer 104 have been described in detail in the embodiment of FIG. 1, so that details thereof are not repeated. The method for forming the phase shift layer 104 is, for example, a chemical vapor deposition method or a physical vapor deposition method. The method for forming the opening 108 is, for example, to perform a patterning process to the phase shift layer 104.

A transparent material layer 106c is formed on the phase shift layer 104, and the transparent material layer 106c is filled in the opening 108. A material of the transparent material layer 106c is, for example, a transparent material such as silicon dioxide, etc. The method for forming the transparent material layer 106c is, for example, the chemical vapor deposition method or the spin coating method. In the present embodiment, the material of the transparent material layer 106c is exemplified as silicon dioxide, and the method for forming the transparent material layer 106c is exemplified as the chemical vapor deposition method.

Referring to FIG. 3B, a planarization process is selectively performed to the transparent material layer 106c, such that the transparent material layer 106c may have a planar surface. The planarization process is, for example, a chemical mechanical polishing process.

Referring to FIG. 3C, a patterned photoresist layer 110 is formed on the transparent material layer 106c above the opening 108. A material of the patterned photoresist layer 110 can be a positive photoresist material or a negative photoresist material. The patterned photoresist layer 110 is, for example, formed through a photolithography process. In the photolithography process used for forming the patterned photoresist layer 110, an adopted exposure process is, for example, the partial irradiation process. The partial irradiation process is, for example, the electron beam irradiation process. Moreover, those skilled in the art may correspondingly adjust the region irradiated by the partial irradiation process based on selection of the photoresist material (for example, the positive photoresist material or the negative photoresist material), and detail thereof is not repeated.

Referring to FIG. 3D, the transparent material layer 106c uncovered by the patterned photoresist layer 110 is removed to form the transparent layer 106 in the opening 108. The extinction coefficient of the transparent layer 106 is, for example, 0. The refractive index of the transparent layer 106 is, for example, greater than 1. The method for removing the transparent material layer 106c uncovered by the patterned photoresist layer 110 is, for example, a dry etching method.

The patterned photoresist layer 110 is removed to fabricate the phase shift mask 100. The method for removing the patterned photoresist layer 110 is, for example, a dry stripping method or a wet stripping method.

According to the above embodiment, it is known that the phase shift mask 100 can be easily fabricated according to the above method, and the attenuation magnitude of the exposure light is decreased by disposing the transparent layer 106 in the opening 108 of the phase shift layer 104, so that the phase shift layer 100 may have larger DOF window, so as to achieve better pattern transfer capability.

In summary, in the phase shift mask and the manufacturing method thereof, the transparent layer disposed in the opening of the phase shift layer can be used to decrease the attenuation magnitude of the exposure light, so as to improve the DOF window of the phase shift mask, and accordingly improve the pattern transfer capability.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A phase shift mask, comprising:
a substrate;
a phase shift layer, disposed on the substrate, and having an opening; and
a transparent layer, disposed in the opening.

2. The phase shift mask as claimed in claim 1, wherein a material of the phase shift layer comprises metal silicide, metal fluoride, metal silicon oxide, metal silicon nitride, metal silicon oxynitride, metal silicon carbon oxide, metal silicon carbonitride, metal silicon oxycarbonitride, alloy thin-layer, metal thin-layer or a combination thereof.

3. The phase shift mask as claimed in claim 1, wherein an extinction coefficient of the transparent layer is 0.

4. The phase shift mask as claimed in claim 1, wherein a refractive index of the transparent layer is greater than 1.

5. The phase shift mask as claimed in claim 1, wherein the transparent layer, has a planar surface.

6. The phase shift mask as claimed in claim 1, wherein a height of the transparent layer is higher than, equal to or lower than a height of the phase shift layer.

7. The phase shift mask as claimed in claim 1, wherein a material of the transparent layer is a crosslinking material or silicon dioxide.

8. The phase shift mask as claimed in claim 7, wherein the crosslinking material comprises hybrid organic siloxane polymer (HOSP), methyl silsesquioxane (MSQ) or hydrogen silsesquioxane (HSQ).

9. The phase shift mask as claimed in claim 1, wherein the phase shift mask is used for forming a pattern in an isolation region.

10. A manufacturing method of a phase shift mask, comprising:
forming a phase shift layer on a substrate, wherein the phase shift layer has an opening; and
forming a transparent layer in the opening.

11. The manufacturing method of the phase shift mask as claimed in claim 10, wherein an extinction coefficient of the transparent layer is 0.

12. The manufacturing method of the phase shift mask as claimed in claim 10, wherein a refractive index of the transparent layer is greater than 1.

13. The manufacturing method of the phase shift mask as claimed in claim 10, wherein a method for foil ling the transparent layer comprises:
forming a transparent material layer on the phase shift layer, and filling the transparent material layer in the opening;
performing a partial irradiation process to the transparent material layer in a region of the opening, such that a crosslinking degree of the transparent material layer in the region of the opening is greater than a crosslinking degree of the transparent material layer outside the region of the opening; and
performing a developing process to remove the transparent material layer that is not processed with the partial irradiation process.

14. The manufacturing method of the phase shift mask as claimed in claim 13, wherein a bonding structure of a component of the transparent material layer that is not processed with the partial irradiation process is a cage structure, and a bonding structure of the component of the transparent material layer processed with the partial irradiation process is a network structure.

15. The manufacturing method of the phase shift mask as claimed in claim 13, wherein the partial irradiation process comprises an electron beam irradiation process.

16. The manufacturing method of the phase shift mask as claimed in claim 10, wherein a method for forming the transparent layer comprises:
forming a transparent material layer on the phase shift layer, and filling the transparent material layer in the opening;
forming a patterned photoresist layer on the transparent material layer above the opening;
removing the transparent material layer uncovered by the patterned photoresist layer; and
removing the patterned photoresist layer.

17. The manufacturing method of the phase shift mask as claimed in claim 16, further comprising:
performing a planarization process to the transparent material layer before forming the patterned photoresist layer.

18. The manufacturing method of the phase shift mask as claimed in claim 17, wherein the planarization process is a chemical mechanical polishing process.

19. The manufacturing method of the phase shift mask as claimed in claim 16, wherein in a photolithography process used for forming the patterned photoresist layer, an adopted exposure process comprises a partial irradiation process.

20. The manufacturing method of the phase shift mask as claimed in claim 19, wherein the partial irradiation process comprises an electron beam irradiation process.
